(19) United States
(12) Patent Application Publication
(10) Pub. No.: US 2023/0110624 A1
(43) Pub. Date: Apr. 13, 2023

(54) Hall Effect Prism Sensor

(71) Applicant: Lexmark International, Inc., Lexington, KY (US)

(72) Inventors: John Douglas Anderson, Lexington, KY (US); Scott Richard Castle, Lexington, KY (US); Keith Bryan Hardin, Lexington, KY (US); Robert Henry Muyskens, Lexington, KY (US)

(21) Appl. No.: 18/081,427

(22) Filed: Dec. 14, 2022

Related U.S. Application Data
(62) Division of application No. 16/816,948, filed on Mar. 12, 2020, now abandoned.
(60) Provisional application No. 62/822,518, filed on Mar. 22, 2019.

(51) Int. Cl. G01R 33/07; H01L 21/302

(52) U.S. Cl. CPC G01R 33/072; H01L 21/302; H01L 43/065; H01L 29/82

(57) ABSTRACT

A physically unclonable function is an object that has characteristics that make it extremely difficult or impossible to copy. An array of randomly dispersed hard (magnetized) and soft (non-magnetized) magnetic particles that may be conducting or nonconducting that are disbursed in a binder create a particular magnetic field or capacitive pattern on the surface. This surface magnetic field and capacitive variations can be considered to be a unique pattern similar to fingerprint. The Hall effect prism is a sensor that measures the effects of these patterns by sensing the deformation of currents or electric potential flowing within or around a resistive substrate material that exhibits a substantial Hall effect coefficient.

### CROSS REFERENCES TO RELATED APPLICATIONS

This application claims priority as a divisional application to U.S. non-provisional patent application Ser. No. 16/816,948, filed Mar. 12, 2020, titled “Hall Effect Prism Sensor,” the content of which is hereby incorporated by reference herein in its entirety.

### BACKGROUND

The present disclosure relates generally to use of Hall effect prisms to measure surface magnetic field and capacitive variations of magnetized particles randomly positioned and oriented, but fixed in a substrate.

### SUMMARY

A physically unclonable function is an object that has characteristics that make it extremely difficult or impossible to copy. An array of randomly dispersed hard (magnetized) and soft (non-magnetized) magnetic particles that may be conducting or nonconducting that are disbursed in a binder create a particular magnetic field or capacitive pattern on the surface. This surface magnetic field and capacitive variations can be considered to be a unique pattern similar to fingerprint. The Hall effect prism is a sensor that measures the effects of these patterns by sensing the deformation of currents or electric potential flowing within or around a resistive substrate material that exhibits a substantial Hall effect coefficient.

### BRIEF DESCRIPTION OF THE DRAWINGS

The above-mentioned and other features and advantages of the disclosed embodiments, and the manner of attaining them, will become more apparent and will be better understood by reference to the following description of the disclosed embodiments in conjunction with the accompanying drawings.

FIG. 1 shows a Hall plate current distribution with bias current source and sensing terminals without the presence of a magnetic field.

FIG. 2 shows a Hall plate current distribution presence of a magnetic field normal to the plate.

FIG. 3 shows a Hall plate current distribution due to the presence of small magnets.

FIG. 4 is a top view over a sensor array substrate layer showing a distribution of surface electrodes.

FIG. 5 is a cross section of the sensor array substrate layer in FIG. 4.

FIG. 6 shows an array of analog switches that selects the bias current (or voltage) source locations between to any two pads and the differential analog amplifier to measure the potential difference between any two sensor pads.

FIG. 7 shows current lines in a cross section without an external magnetic field.

FIG. 8 shows conducting pads on the top and bottom of a resistive slab.

FIG. 9 shows isolated conducting through a resistive substrate.

### DETAILED DESCRIPTION

It is to be understood that the present disclosure is not limited in its application to the details of construction and the arrangement of components set forth in the following description or illustrated in the drawings. The present disclosure is capable of other embodiments and of being practiced or of being carried out in various ways. Also, it is to be understood that the phraseology and terminology used herein is for the purpose of description and should not be regarded as limiting. As used herein, the terms “having,” “containing,” “including,” “comprising,” and the like are open ended terms that indicate the presence of stated elements or features, but do not preclude additional elements or features. The articles “a,” “an,” and “the” are intended to include the plural as well as the singular, unless the context clearly indicates otherwise. The use of “including,” “comprising,” or “having,” and variations thereof herein is meant to encompass the items listed thereafter and equivalents thereof as well as additional items.

Terms such as “about” and the like have a contextual meaning, are used to describe various characteristics of an object, and such terms have their ordinary and customary meaning to persons of ordinary skill in the pertinent art. Terms such as “about” and the like, in a first context mean “approximately” to an extent as understood by persons of ordinary skill in the pertinent art; and, in a second context, are used to describe various characteristics of an object, and in such second context mean “within a small percentage of” as understood by persons of ordinary skill in the pertinent art.

Unless limited otherwise, the terms “connected,” “coupled,” and “mounted,” and variations thereof herein are used broadly and encompass direct and indirect connections, couplings, and mountings. In addition, the terms “connected” and “coupled” and variations thereof are not restricted to physical or mechanical connections or couplings. Spatially relative terms such as “top,” “bottom,” “front,” “back,” “rear,” and “side,” “under,” “below,” “lower,” “over,” “upper,” and the like, are used for ease of description to explain the positioning of one element relative to a second element. These terms are intended to encompass different orientations of the device in addition to different orientations than those depicted in the figures. Further, terms such as “first,” “second,” and the like, are also used to describe various elements, regions, sections, etc., and are also not intended to be limiting. Like terms refer to like elements throughout the description.

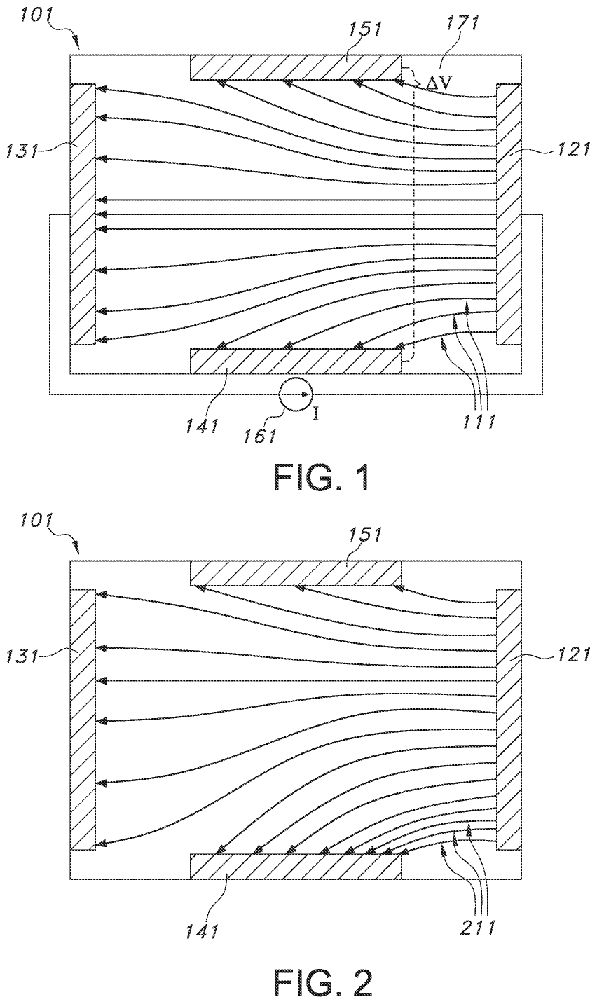

A Physically Unclonable Function (PUF) is an object that has characteristics that make it extremely difficult or impossible to copy. An array of randomly dispersed hard (magnetized) and soft (non-magnetized) magnetic particles that may be conducting or nonconducting that are disbursed in a binder that create a particular magnetic field or capacitive pattern on the surface. This surface magnetic field and capacitive variations can be considered to be a unique pattern similar to fingerprint. The Hall Effect Prism is a sensor that measures the effects of these patterns by sensing the deformation of currents or electric potential flowing within or around a resistive substrate material that exhibits a substantial Hall effect coefficient. A person or ordinary skill in the art would recognize that the prism sensor of this invention is not limited to Hall effect measurements, but could be applied to any magnetic field sensing device. “Resistive substrate” or “substrate” will be understood to mean a material that exhibits a substantial Hall effect coefficient. These materials include but are not limited to Silicon (Si), gallium arsenide (GaAs), indium arsenide (InAs), indium phosphide (InP), indium antimonide (InSb), graphene (an allotrope of carbon (C)), and Bismuth (Bi) for example. The sensing is achieved by direct conductive contact to the substrate material or capacitively coupling to the substrate. The prior art consists of Hall effect sensors that have the geometry shown in FIG. 1. There are several geometries that have been used in the past, attempting to find the average magnetic field through the material.

In FIG. 1, the currents 111 are traveling in a Hall plate 101 along the arrow line paths from the right to left from the source terminals 121, 131, and to the sense terminals 141, 151 of the top and bottom. The current lines 111 are created by the bias current source 161 connected to the source terminals 121 and 131. Under the influence of a normal magnetic field the currents 211 are moved by the forces on the electrons to a pattern more like FIG. 2. A higher potential of the bottom terminal than the top causes a differential voltage (ΔV) 171 that is proportional to the magnetic field intensity that are normal to the Hall plate. This is the geometry and operation of a classic Hall effect sensor.

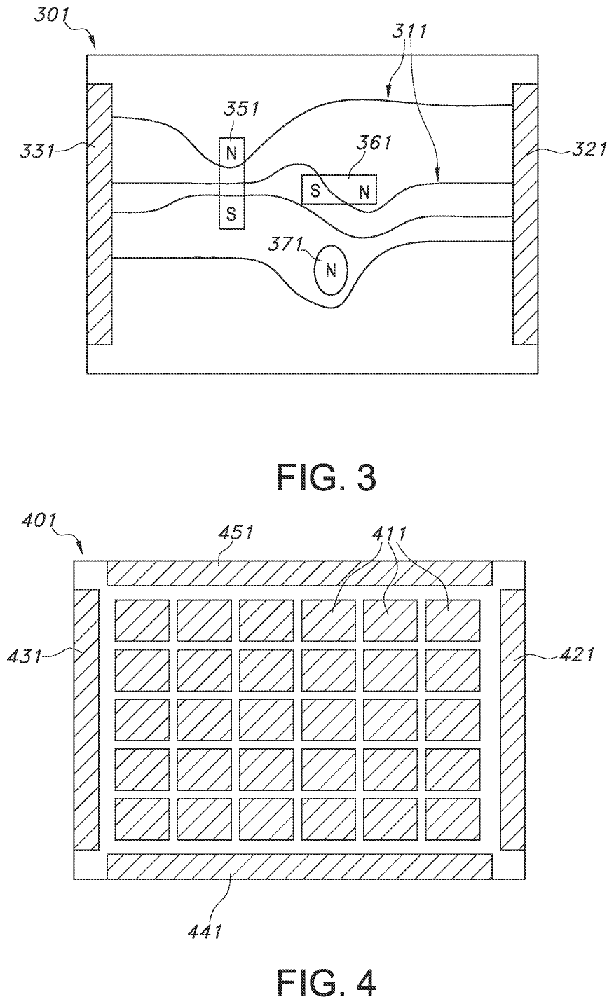

Most applications are looking for the magnetic field at one spot in space or the average over the surface area of the Hall plate. However, this invention solves a different problem. The magnetic field is created by an array of many small magnets represented by just three magnets 351, 361, 371 in FIG. 3 that are distributed within a binder matrix. The goal is not to measure a spot or average value over the plate, but to characterize a unique effect of the object creating the field. Small magnets placed near to the resistive substrate will deflect the current pattern due to the normal magnetic field in their local region. FIG. 3 shows this change in the current lines 311 due to the small magnets with the bias current applied between electrodes 321 and 331. The change in current will also result in change in potentials throughout the surface of the resistive sheet of the Hall plate 301. These potential changes will be measurably related to the normal magnetic field near the electrodes 411.

If the magnet features are small with respect to the substrate size, then the current lines will be more uniform when away from the normal magnetic fields. There is a desire to understand this distortion on the order of the size of the magnets. For this an array of small magnets, many sense locations are necessary.

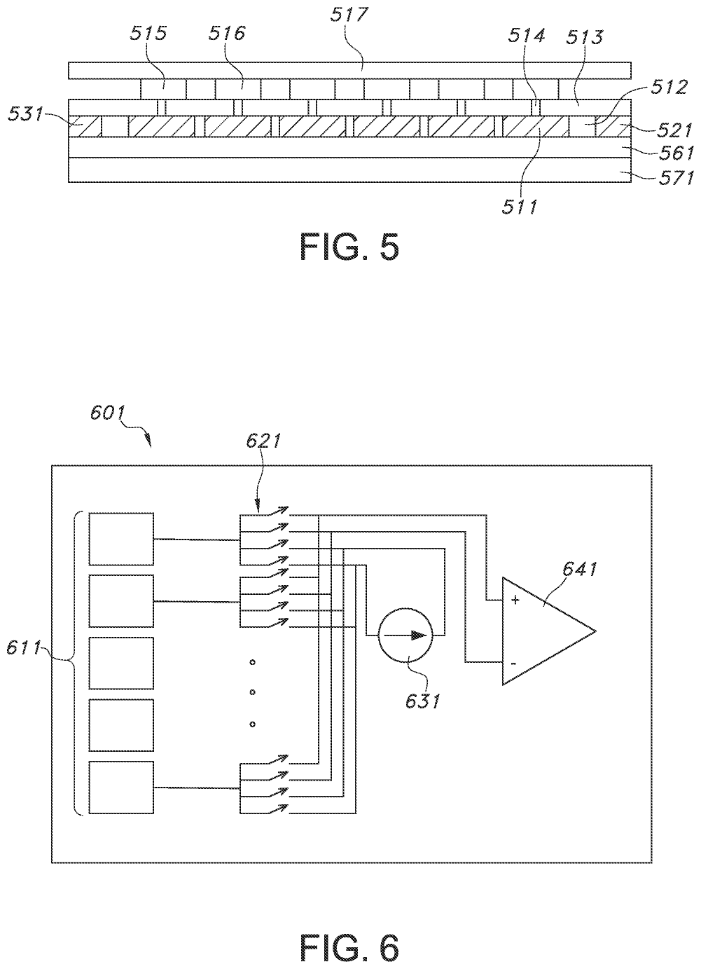

FIGS. 4 and 5 show a substrate with an array 401 of electrodes 411 on top to measure the potentials as the currents are deflected by magnetic field lines. The electrode or conducting pads 411 are not necessarily shown to dimensional scale with respect to the Hall plate or each other. Depending on the design optimization, the conducting pad size to spacing between the pads may be any ratio. Each pad geometry may not be the same, or even rectangular. Circles, squares, or arbitrary geometries are acceptable. Note that the deflection is related to the magnetic field, but is not a direct measurement of the field value. Since there are several magnets along the current path then each will interact with the current causing a variety of distortions in the potential pattern. The potential variations are not independent if the magnets are close together. It is, however, a repeatable measurement that can be made if the field levels are repeated in the substrate and the source positions are the same. Each of the potential measurements are preferred to be a differential measurement. However, absolute voltage measurements can also give a unique potential pattern. Differential values can then be found by evaluating the difference in absolute measurements. The differential potential measurement gives a better signal to noise measurement when the potentials are similar in amplitude.

FIG. 4 is the top view looking over the sensor array substrate layer with optional current bias electrodes 421, 431, 441 and 451. The additional layers are stacked on top of this substrate to create interconnect to the substrate and route wiring channels to go to the required bias and measurement circuitry. Typical Hall effect sensors use four or five electrodes for each Hall plate. FIG. 4 has 30 interior electrodes 411 on one Hall plate giving a much higher resolution of interior potentials. This is a substantially greater quantity of conducting pad electrodes compared to a typical sensor. The conducting pad array quantity is a minimum of 9 but preferred to be greater than 49. FIG. 5 is a cross section of the stack up of the layers. The conductor pad connections to the substrate 511 may be plated on the surface of the substrate or a pressure contact to the surface of the substrate. As said the geometry of the conducting pad is not critical. They may be a square, rectangle, circle, or any arbitrary shape. Each element in the array may be similar for convenience or different to add complexity of the reader. For a high density packing of conducting pads would be a hexagon array pattern of circles or hexagon pads. The conducting pads must allow for a current to flow within the substrate. The gaps between the conducting pads 512 isolate one conducting pad from another which can be air or any non-conducting filler material. The layer 571 is an insulating material that isolates the sensing area substrate 561 from the devices being measured that are below the insulating layer 571 for this example. The layer containing items 513 and 514 is an insulating layer material 513 with vertical conducting connections from the conducting pads 511 to a wiring layer denoted by items 515 and 516. The conducting wire interconnects 515 route signals to the circuitry shown in FIG. 6. The gap between the signals 516 are isolating materials between the wires. Depending of the design, addition wiring layers may be needed to connect all the conducting pads to the required circuitry but not shown. The top layer 571 is an optional insulating layer to protect the wiring. The top layer dielectric 517 separates the wiring represented by 515 and 516 from optional additional wiring layers if needed.

The optional longer segment electrodes around the edge 531 and 521 provides a way to get a more uniform current flow through the substrate to lower the complexity of the sensor. A current or voltage source may be applied to any two electrodes within the array or edge conducting pads. This will cause the potential gradient distributed within the substrate. Then the potential measurements can then be made between any two conducting pads. The measurement of the two source locations is the trivial answer that does not yield any needed information. However, all the other combinations will give a reaction to the magnetic field patterns due to the magnetic distribution near the substrate.

One skilled in the art would recognize that the sensor size can be scaled with respect to the magnet size. Printed circuits are used for larger sensor sizes and resolutions. Semiconductor techniques can be used for the smaller size sensing areas.

FIG. 5 shows a resistive substrate layer 561 for direct contact to the sensing pad. The resistive layer 561 could alternatively be a dielectric layer with the resistive substrate layer shown as 471 for capacitive coupling.

There are many ways to implement this Hall prism effect by making modifications to touch sensing or camera sensor devices.

Another embodiment is provided by applying the source current to any combination of the side electrodes. This emphasizes different regions of the magnetic fields within the structure and results in different outputs. This can be done by using analog switches to route the source and measurement locations within the array of contacts.

A result is that the reader can be given a command to vary the source locations which are filtered by the magnetic PUF to result in a different resultant output vector.

In another embodiment, the source locations for the current can be applied to any combination of the surface contact or coupling locations. The pads can be given an array number in terms of rows and columns. In this way, any source pattern of one more positive or negative source locations results in a different pattern on the voltage measuring pad locations. By choosing the different source locations the sensitivity of the potential changes within the array can be tuned to the magnets under the sensor area.

FIG. 6 shows a representative schematic 601 of an array of analog switches 621 that multiplexes the current 631 (or voltage) source to any two pads 611 and the differential analog amplifier 641 to measure the potential different between two pads. The quantity of 611 conducting pad shown is 6 but this represents arrays of quantities that are substantial greater than a minimum of 9 but preferred to be greater than 49. This design will allow both differential or absolute measurements as previously discussed. The measuring device may be a combination of amplifiers 641 and analog to digital converter (ADC) to get sufficient gain or amplitude control. If a reduced number of switches are desired, then the source could be permanently attached to two pads which may include the longer pads shown in FIG. 4.

The source may be a direct current (“DC”) for direct measurement of the voltage potential distribution. An alternating current (“AC”) may also be used which would allow capacitive coupling that would not require direct conduction contact to the substrate resistive layer. The device being measured is filled with conducting particles that are magnetized. This will also give a different frequency response for different frequencies of operation. The embedding of non-magnetic conductive wires would give an altered response. The AC or time varying source may have different profiles. Sinusoidal, square, triangular, trapezoidal, exponential and other stimulus would all give a different response. The voltage potentials may also be sampled by a “sample and hold” circuity. This will allow a simultaneous sampling of the entire array at one time. This is a very similar technique to exposure control of camera sensors.

In another embodiment, the substrate may be expanded beyond a resistive substrate materials including a number of semiconductor device materials. The simple resistive operation has both positive (holes) and negative (electron) carriers that are available to be influenced by the magnetic field. The substrate may be a material with majority carries being a P (holes) or N (electrons). The deposition of these materials is the same as the current art for single Hall effect sensors that exhibit the substantial Hall coefficient. However, this invention has an array in two dimensions of spaced electrodes distributed along the surface of the substrate.

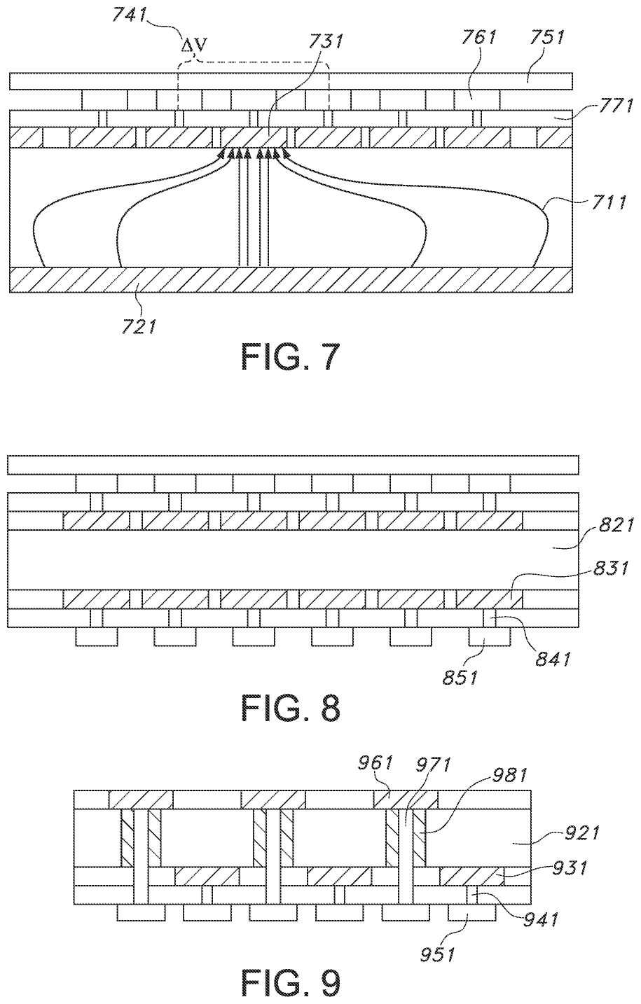

In another embodiment, the substrate material can be made thicker stretching the into a 3D sensor. This would allow magnetic fields to be measured in the direction that is tangential to the sensor array surface. FIG. 7 shows the currents flow lines from a conductive plate 721 to the top source target pad 731. The sense pads are a 2D array so that magnetic fields that flow from left to right or in or out of the page can be measured. Using the previously disclosed embodiments the system can give a response to any 3D vector of magnetic field source. The current flow lines 711 result from not having a magnetic field present. The ΔV shown is the potential difference between two conducting pads that are adjacent to the right and left of pad 731. This ΔV will respond to magnetic fields that are in the direction in and out of the cross section shown which is in and out of the page. The current lines 711 will be distorted when a magnetic field is present. Magnetic fields that are in the direction from the right and left will result is a different ΔV 741 on conducting pads that are adjacent to the ones that are above and below the page of the cross section shown. This effect is not limited to the adjacent pads but could be wider in separation. The preferred orientation would be the adjacent ones. The layer 771 above conducting pads 731 and adjacent one is an insulating layer with conducting connections between the pads and the wiring channels 761. The top layer 751 is an optional insulating layer. As said previously, there may be any number of wiring layers with vertical connections.

In another embodiment shown in FIG. 8, the bottom conducting plate 721 in FIG. 7 can be replaced with an array of pads while keeping the array of pads in the top section of the resistive region. This would allow the same programmability to emphasize vertical current flow from one region over another as well as scaling the current densities within the resistive region. With this configuration the surface electrodes on the substrate will be influenced by the magnetic field on all directions depending on the applied current path. This allows all field directions to affect the potential distribution to the surface pads. This gives impressive flexibility measuring high resolution fields. A resistive substrate material 821 is used to exhibit the Hall effect in all directions. The pads 831, vertical connection 841 and wiring channels 851 perform the same functions as pads 511, 731, vertical connections 841,514 and wiring channels 516 respectively.

A soft ferrite material layer can be added to the back side of the sensor to increase the field on the sensor side of the voltage measuring pads. This would be placed anywhere above the measuring pads in FIG. 5 or below the conducting common source pad in FIG. 7 or either sides of above or below FIG. 8 and FIG. 9. This ferrite layer would also magnetically shield the sensing area from magnetic fields created by the auxiliary circuitry that operates the scanning of the sensor.

In another embodiment, a reader or sensor is made unique by inserting a filter or key that is a thin layer of magnet PUF material that will perturb the magnetic fields between the sensor and the PUF device being measured. This thin key layer is present when measuring the target PUF object is present to enroll or record the superposition of object and key. This key would create a distorting field of the test PUF object. The additional thin key layer could then be removed and used as a two-level authentication. The target and the key insert would have to be recombined to repeat the measurement to identify the total fingerprint for authentication. For additional security, the key may be shipped by a different method than the PUF object device.

An example sensor can be constructed using rigid or flexible material. A ceramic base could be used for a rigid device with a laminated or coated process to apply the resistive substrate material. The layering of the material would be like any printed circuit board (“PCB”) or package processes. This implementation could just as easily be part of a semiconductor process like complementary metal—oxide—semiconductor (“CMOS”) or charged-coupled device (“CCD”) camera sensors. In these cases, the medium is light sensitive but could be replaced by a resistive substrate material.

The sensor can be translated by 0.5 cells to double the resolution in the X and Y

direction.

As the array of sensor pads grows in FIG. 6, the switch circuitry grows in complexity. Row and column addressability techniques can be used to organize the sensor reading or sourcing of the substrate pads. These techniques are similarly used in light cameras sensors or memory devices.

Additional combinations of potential variations can be created by stacking alternating layers of electrode and substrate layers. This will give indications of how the fields are bending as they progress through the layers. The layers may be isolated from each other or bonded together to allow current to flow from the top surface of the stack to the bottom of the stack. This will allow dynamic control of the sensitivity in all directions as well.

An additional feature is a via that can connect to a layer in the stack but be isolated from the bulk material. The FIG. 8 implementation requires that connections are made on both side of the substrate. This has the complexity of getting the wiring through or around the substrate. FIG. 9 shows isolated conducting through a resistive substrate 921 to make the connection to the top pad 961. For this implementation the conducting via 971 must be isolated from the substrate by the insulator 981 so that the current primarily flows from top to bottom when measuring X and Y directed magnetic field effects.

A wiring channel 951 connects the center conducting via 941 from the substrate 921. The conducting pad 961 are shown on the top of the stackup. The conducting via 941, 971 connect the wiring channels to their respective conducting pads 931 and 961 that are connected to the resistive substrate. While the dielectric material will obstruct the current flow, it will stop the conducting via from shorting the vertical flow of the current.

One skilled in the art would recognize that the structures found in FIGS. 4-5 and 7-9 of this invention are similar to existing systems that implement the scanning of the potential voltages of the sensor surface create a capacitive sensor. The circuitry found in FIG. 6 can operate as a fingerprint capacitive sensor also. The primary difference is that the system would have a best mode of providing an analog output of each locations to give a fine resolution each potential difference. Many fingerprint scanners look at the capacitance change to give a threshold digital output. This type of output could be used for a lower confidence that the PUF device has a unique match to the field pattern due to the electric field and the capacitive quality.

The sensor in FIG. 9 is particularly useful for capacitive and magnetic sensing. This is because the top conducting pads can be placed in close proximity to the PUF object which be on the top of this drawing cross section. Minimizing the distance from the magnetic or conducting material in the PUF will optimize the sensitivity to measuring the magnetic and electric field respectively.

Sensor calibration may be necessary to compensate for environmental variations which can affect sensor response. A baseline signal response will be recorded across one or multiple terminal pairs prior to introducing the magnetic/PUF material sample. Baseline calibration signal response information will be used to adjust test measurement readings as needed in order to compensate for environmental conditions. In some applications a compensating signal input may be applied to one or more electrodes in order to calibrate the response reading within another test electrode.

A soft ferrite material may be placed over the sensor to block external fields during the calibration process. This is then removed for the set of the magnetic/PUF material. This soft ferrite can be integrated into a sensor covers that automatically retracts or is manually removed for use.

We claim:

1. A method of characterizing the effect of an object on a magnetic field comprising:
creating a magnetic field with an array of small magnets distributed within a binder matrix; and
measuring the change in potentials throughout the surface of a resistive substrate caused by the small magnets placed near to the resistive substrate that deflect the current pattern due to the normal magnetic field,
wherein sensing is achieved by direct conductive contact to the substrate material or capacitively coupling through the substrate.

2. A sensor array substrate comprising:
a sensor array substrate layer;
additional layers stacked on top of the substrate to create interconnectivity to the substrate and route wiring channels to go to required bias and measurement circuitry;
conductor pad connections to the substrate, wherein the conducting pads allow a current to flow within the substrate and the gaps between the conducting pads isolate one conducting pad from another; and
an insulating material that isolates the sensing area substrate from devices being measured.

3. The sensor array of claim 2, wherein the conductor pad connections to the substrate may be plated on the surface of the substrate.

4. The sensor array of claim 2, wherein the conducting pad geometry may be a square, rectangle, circle, or any arbitrary shape.

5. The sensor array of claim 2, wherein the conducting pads would be a hexagon array pattern of circles or hexagon pads for a high density packing.

6. The sensor array of claim 2, wherein the resistive layer for direct contact to the sensing pad could alternatively be a dielectric layer with the resistive substrate layer for capacitive coupling.

7. The sensor array of claim 2, wherein the source locations for the current can be applied to any combination of the surface contact or coupling locations in order to tune the sensitivity of the potential changes within the array to the magnets under the sensor area.

8. The sensor array of claim 2, wherein the substrate may be expanded beyond a resistive substrate material to include a number of semiconductor device materials.

9. A sensor array substrate comprising:
a sensor array substrate layer;
additional layers stacked on top of the substrate to create interconnectivity to the substrate and route wiring channels to go to required bias and measurement circuitry;
conductor pad connections to the substrate, wherein the conducting pads allow a current to flow within the substrate and the gaps between the conducting pads isolate one conducting pad from another;
an array of pads in place of a bottom conducting plate; and
an insulating material that isolates the sensing area substrate from devices being measured.

10. The sensor array of claim 9, wherein a soft ferrite material layer is added to the back side of the sensor to increase the field on the sensor side of the voltage measuring pads.

11. The sensor of claim 2, wherein a filter or key that is a thin layer of magnetic PUF material is inserted over the sensor that will perturb the magnetic fields between the sensor and the PUF device being measured.
